(19) United States
(12) Patent Application Publication
(10) Pub. No.: US 2012/0171944 A1
(43) Pub. Date: Jul. 5, 2012

(54) INSULATION SYSTEM FOR A DATA CENTER

(75) Inventors: Dirk Heidenberger, Appen (DE); Hans J. Hoffmann, Sarstedt (DE)

(73) Assignee: HANNO-WERK GMBH & CO. KG, Laatzen (DE)

(21) Appl. No.: 13/392,751

(22) PCT Filed: Aug. 27, 2010
(86) PCT No.: PCT/DE10/00997

§ 371 Date: Mar. 9, 2012

(30) Foreign Application Priority Data
Aug. 28, 2009 (DE) 102009039014.6
Aug. 31, 2009 (DE) 102009039.315.3
Jan. 19, 2010 (DE) 102010005141.1

(51) Int. Cl. H05K 5/02

(52) U.S. Cl. 454/184

(57) ABSTRACT

The invention relates to an insulation system for a data center.

The invention relates to an insulation system for a computer center.

A cooling system for a computer center is known from U.S. Pat. No. 6,672,955 B2, in which the electronic devices accommodated in equipment and/or server cabinet rows, particularly servers, are provided with cold air from a so-called cold corridor. The cold air, which is cooled in a heat exchanger outside of the computer room, gets into a double floor of the computer room using fans, and then gets into the cold corridor in targeted manner, by way of pre-determined floor-side openings.

The floor of a computer center is generally mounted on pillars, in order to run lines and cold air or cold air within the floor. In general language usage, one speaks of a double floor. Because cold air is introduced into this double floor, the double floor can also be called a pressurized floor.

Proceeding from this state of the art, the invention is based on the task of structuring the cooling provided in the computer center even more efficiently, and, in particular, of clearly lowering the energy costs in the computer center.

This task is accomplished, according to the invention, by means of an insulation system having the characteristics of claim 1. Further advantageous embodiments are evident from the dependent claims and the description.

The insulation system according to the invention, for a computer center, comprises a computer room having equipment or service cabinet rows whose equipment or server cabinets are positioned on a double floor, whereby floor-side air inflow or air intake openings that are not intended for targeted feed of cold air are provided with a foam material, according to the invention.

Because the air inflow or air intake openings not intended for targeted feed of cold air are provided with a foam material, thermal insulation of the double floor is achieved in surprisingly simple manner, whereby cold air conducted in the double floor flows essentially only through the openings actually intended for this purpose. For this purpose, the air inflow or air intake openings are preferably sealed off with the foam material as tightly as possible.

As a result, a significant saving of energy costs in the computer center is achieved, in surprisingly simple manner. In this connection, the invention is based on the recognition that the aforementioned air inflow or air intake openings as well as other undesirable outlets in the double floor lead to an undesirable drop in pressure of the cold air within the double floor of a computer center. Because such openings are closed off by means of foam material, or made leak-proof or at least more leak-proof, according to the invention, the desired cold air in the double floor can be operated with less energy expenditure of the source(s) that generate(s) the cold air and the agent(s) that produce(s) the cold air. Effective thermal insulation of the double floor is achieved in simple manner, whereby the foam material simultaneously has an advantageous effect as noise insulation.

Installation of the foam material in an air inflow or air intake opening is extremely simple and cost-friendly, in this connection, whereby the foam material is preferably a soft foam that can be brought into a compressed state, particularly by hand, by compressing it, and expands or expands again after it is let go.

The air inflow or air intake openings can preferably be openings for passing through various lines and/or installation materials, particularly those for passing through cables, very particularly those for passing through a server and/or network cable system. In particular, these can be such air inflow or air intake openings that are already present in the double floor, but for which passing through various lines and/or installation materials is only planned at a later time.

Very generally, the air inflow or air intake openings are those that lead to undesirable pressure losses in the double floor. In this connection, these air inflow or air intake openings can be introduced into the double floor in planned or unintentional manner.

Preferably, such air inflow or air intake openings that are disposed in the panels that form the double floor, particularly as a hole punch-out, or adjacent to the panels that form the double floor, particularly as a cut-out in the edge region or by means of the absence of one or more panels in the edge region, are provided with foam material.

A further development of the invention provides that the foam material is configured in the form of a sphere, a cushion, but preferably in the shape of a panel.

In order to adapt the foam material to the shape of the air inflow or air intake openings in the simplest possible manner, and to enclose existing lines, it can be advantageous if the foam material is preferably pre-punched or perforated into individual rectangles, particularly preferably into individual squares. These can be removed, re-inserted or separated from one another for a short time, for accommodating one or more lines and/or installation materials. The starting foam material has dimensions of 620 mm×620 mm×50 mm, for example. With such a foam material, it is usually possible to close off all the undesirable air inflow or air intake openings in a computer center. Smaller dimensions or other shapes can be produced by means of simply dividing the foam material along the perforations or pre-punched areas.

The air inflow or air intake openings can have the most varied shapes. They can be configured to be round or polygonal, for example.

A further development of the invention provides that the foam material is flame-resistant or non-flammable.

In order to obtain great density and sound absorption, it can be advantageous if the foam material is a melamine resin foam. Melamine resin foam is a flexible, open-cell and very light soft foam material. It possesses great sound absorption and is temperature-resistant. Because of the fine-celled structure, melamine resin foam possesses a relatively slight heat conductivity at normal temperature, so that the cold air conducted in the double floor is not heated. Melamine resin foam is therefore particularly well suited for thermal insulation. It is furthermore advantageous that melamine resin foam meets the requirements of construction material class B1 and is highly flame-resistant.

For specific application cases, it can be advantageous if the foam material is an EPS polystyrene particle foam. For specific application cases, it can be advantageous if the foam material is an XPS polystyrene extruder foam. For other specific application cases, it can be advantageous if the foam material is a PUR hard or soft foam. For other specific application cases, it can be advantageous if the foam material is an EPE, an EPP, or an EPO polyolefin foam. For yet other specific application cases, it can be advantageous if the foam material is a PES polyester foam. For yet other specific application cases, it can be advantageous if the foam material a PF phenolic resin foam. For other specific application cases, yet again, it can be advantageous if the foam material is a UF urea formaldehyde foam. For other specific application cases, yet again, it can be advantageous if the foam material is a PET polyethylene terephthalate foam. It can be particularly advantageous if the foam material is a melamine resin foam.

For specific purposes of use, it can be advantageous if the foam material is a cell natural rubber, preferably NBR, EPDM, NBS, or CR. For specific purposes of use, it can be advantageous if the foam material is a cell rubber, preferably a moss rubber. For other specific purposes of use, it can be advantageous if the foam material is a PVC cell plastic. For other specific purposes of use, it can be advantageous if the foam material is an ML multi-layer light construction panel. For other specific purposes of use, yet again, it can be advantageous if the foam material is an HWL wood wool light construction panel.

For specific cases of use, it can be advantageous if the foam material is an impregnated plastic foam material, preferably an acrylate-impregnated PUR foam material.

For specific cases of use, it can be advantageous if the foam material is or has mineral/glass/ceramic wool. For other specific cases of use, it can be advantageous if the foam material is or has a foamed or expanded glass. For other specific cases of use, it can be advantageous if the foam material is or has pearlite or expanded pearlite, silicate, expanded mica or expanded clay, or pumice.

For specific cases of use, it can be advantageous if the foam material is a nonwoven fabric, preferably composed of synthetic, natural and/or mineral fibers. For specific cases of use, it can be advantageous if the foam material is a felt, preferably composed of synthetic, natural and/or mineral fibers. For other specific cases of use, it can be advantageous if the foam material is or has at least one metal foil, preferably an aluminum foil. For other specific cases of use, yet again, it can be advantageous if the foam material is or has at least one plastic film. For yet other specific cases of use, it can be advantageous if the foam material has a bitumen coating.

Cabinets are usually equipped uniformly, in such a manner that the equipment fronts are disposed on one side of the cabinet. In this way, the result is supposed to be achieved that the equipment draws in cold air intended for cooling, uniformly on one side, and gives off the heated air again uniformly on another, usually the opposite side.

It can be advantageous if openings of the front and rear side, but also of the left and/or right side parts as well as of the roof of a partly empty or completely empty accommodation of an equipment or server cabinet, in other words one provided with a smaller electronic device or without an electronic device, are provided with the foam material. The openings to be sealed, preferably as much as possible, with foam material, do not serve, in this connection, for the planned passage of cold air through the equipment or server cabinet. As a result, air conditioning losses resulting from undesirable mixing or eddying of warm and cold air in the equipment or server cabinet, for example, are avoided. The equipment or server cabinet can therefore be thermally insulated in simple, installation-friendly manner. In total, the required cooling is structured to be even more efficient. In this connection, the foam material can be adapted to the situation in extremely flexible manner.

For some cases of use, it can be advantageous if the surface of the foam is compacted. For some cases of use, it can be advantageous if the surface of the foam material is embossed in itself or additionally. For some other cases of use, it can be advantageous if the surface of the foam material is impregnated, in itself or additionally. For some other cases of use, it can be advantageous if the surface of the foam material is coated in itself or additionally, whereby the coating preferably is or has a plastic coating and/or, particularly preferably, a fire protection coating.

It can be advantageous if the foam material has a smooth or preferably an embossed surface compaction. As a result, improved thermal insulation and density are particularly achieved.

1. Insulation system for a computer center, comprising a computer room having equipment or server cabinet rows whose equipment or server cabinets are positioned on a double floor, wherein floor-side air inflow or air intake openings that are not intended for targeted feed of cold air are provided with a foam material.

2. Insulation system according to claim 1, wherein the air inflow or air intake openings are those for passing through various lines and/or installation materials, particularly those for passing through cables, very particularly those for passing through a server and/or network cable system.

3. Insulation system according to claim 1, wherein air inflow or air intake openings are those that lead to undesirable pressure losses in the double floor.

4. Insulation system according to claim 1, wherein air inflow or air intake openings are disposed in the panels that form the double floor, particularly as a hole punch-out, or adjacent to the panels that form the double floor, particularly as a cut-out in the edge region or by means of the absence of one or more panels.

5. Insulation system according to claim 1, wherein the foam material is configured in the form of a sphere, a cushion, but preferably in the shape of a panel.

6. Insulation system according to claim 1, wherein the foam material is pre-punched or perforated, wherein the foam material is preferably pre-punched or perforated into individual rectangles, preferably squares.

7. Insulation system according to claim 1, wherein the foam material is flame-resistant or non-flammable.

8. Insulation system according to claim 1, wherein the foam material is a soft foam.

9. Insulation system according to claim 1, wherein the foam material is an EPS polystyrene particle foam, an XPS polystyrene extruder foam, a PUR hard or soft foam, an EPE, an EPP, or an EPO polyolefin foam, a FEB polyester foam, a PF phenolic resin foam, a UF urea formaldehyde foam, a PET polyethylene terephthalate foam, or preferably a melamine resin foam.

10. Insulation system according to claim 1, wherein the foam material is a cell natural rubber, preferably NBR, EPDM, NBS, or CR, a cell rubber, preferably a moss rubber, a PVC cell plastic, an ML multi-layer light construction panel or an HWL wood wool light construction panel.

11. Insulation system according claim 1, wherein the foam material is an impregnated plastic foam material, preferably an acrylate-impregnated PUR foam material.

12. Insulation system according claim 1, wherein the foam material is or has mineral/glass/ceramic wool, foamed or expanded glass, pearlite or expanded pearlite, silicate, expanded mica or expanded clay, or pumice.

13. Insulation system according claim 1, wherein the foam material is or has a nonwoven fabric, preferably composed of synthetic, natural and/or mineral fibers, a felt, preferably composed of synthetic, natural and/or mineral fibers, at least one metal foil, preferably an aluminum foil, or at least one plastic film.

14. Insulation system according to claim 1, wherein the foam material has a bitumen coating.

15. Insulation system according claim 1, wherein openings of the front and rear side, but also of the left and/or right side parts as well as of the roof of an empty or partly empty accommodation of an equipment or server cabinet, in other words one not provided with an electronic device or with a smaller electronic device, are provided with the foam material.

16. Insulation system according to claim 1, wherein the surface of the foam is compacted, embossed, impregnated and/or coated, wherein the coating preferably is a plastic coating and/or, particularly preferably, a fire protection coating.

17. Insulation system according to claim 1, wherein the foam material has a smooth or preferably an embossed surface compaction.
